(19) United States
(12) Patent Application Publication
(10) Pub. No.: US 2021/0351293 A1
(43) Pub. Date: Nov. 11, 2021

(54) NOVEL GATE STRUCTURE FOR AN LDMOS TRANSISTOR DEVICE

(71) Applicant: GLOBALFOUNDRIES U.S. Inc., Santa Clara, CA (US)

(72) Inventors: Man Gu, Malta, NY (US); Wang Zheng, Ballston Lake, NY (US); Rong-Ting Liou, Malta, NY (US); Haiting Wang, Clifton Park, NY (US); Wenjun Li, Saratoga Spring, NY (US)

(21) Appl. No.: 16/870,356

(22) Filed: May 8, 2020

(51) Int. Cl. H01L 29/78; H01L 29/66

(52) U.S. Cl. CPC H01L 29/7816; H01L 29/66681

(57) ABSTRACT

A device is disclosed that includes a source region positioned in a first doped well region in a semiconductor substrate and a drain region positioned in a second doped well region in the substrate, wherein there is a well gap between the first doped well region and the second doped well region. The device also includes a gate structure that includes a first gate insulation layer positioned above an upper surface of the substrate, wherein the first gate insulation layer extends from a drain-side sidewall of the gate structure to a location above the well gap, and a second gate insulation layer having a first portion positioned above the upper surface of the substrate and a second portion positioned above the first gate insulation layer.

### BACKGROUND

### Field of the Invention

The present disclosure generally relates to various novel embodiments of a gate structure for an LDMOS (Laterally Diffused Metal Oxide Semiconductor) transistor device and various novel methods of making such a gate structure.

### Description of the Related Art

There are two major structural categories of RF MOS transistors in use today. These transistors include DMOS (double-diffused Metal Oxide Semiconductor) devices and LDMOS (laterally diffused Metal Oxide Semiconductor) devices. DMOS and LDMOS devices have unique geometries, unique behaviors and require unique fabrication techniques to fabricate such devices. In recent years, LDMOS devices have been increasingly applied in high voltage and smart power applications. Generally, an LDMOS device has an asymmetric structure with a drift region located between the channel of the LDMOS and the drain region. The drift region includes an isolation structure that is formed in the substrate between the source/drain regions, wherein a portion of the isolation structure is positioned vertically below the gate structure of the LDMOS device. Device designers are under constant pressure to increase the performance capabilities of all transistor devices, including LDMOS devices.

The present disclosure is generally directed to various novel embodiments of a gate structure for an LDMOS device and various novel methods of making such a gate structure.

### SUMMARY

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various novel embodiments of a gate structure for an LDMOS device and various novel methods of making such a gate structure. An illustrative device disclosed herein includes a source region positioned in a first doped well region in a semiconductor substrate and a drain region positioned in a second doped well region in the substrate, wherein there is a well gap between the first doped well region and the second doped well region. The device also includes a gate structure that includes a first gate insulation layer positioned above an upper surface of the substrate, wherein the first gate insulation layer extends from a drain-side sidewall of the gate structure to a location above the well gap, and a second gate insulation layer having a first portion positioned above the upper surface of the substrate and a second portion positioned above the first gate insulation layer.

An illustrative method disclosed herein includes forming an initial gate structure that includes a first gate insulation layer positioned on a semiconductor substrate between a sidewall spacer, forming a patterned etch-mask that covers a first portion of the first gate insulation layer while leaving a second portion of the first gate insulation layer exposed, and performing an etching process to remove the second portion of the first gate insulation layer. In this example, the method also includes removing the patterned etch-mask and forming a conformal second gate insulation layer, wherein the conformal second gate insulation layer has a first portion positioned on the upper surface of the semiconductor substrate and a second portion positioned on the first gate insulation layer.

### BRIEF DESCRIPTION OF THE DRAWINGS

The disclosure may be understood by reference to the following description taken in conjunction with the accompanying drawings, in which like reference numerals identify like elements, and in which:

FIGS. 1-11 depict various novel embodiments of a gate structure for an LDMOS device and various novel methods of making such a gate structure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

As will be readily apparent to those skilled in the art upon a complete reading of the present application, the presently disclosed method may be applicable to a variety of products, including, but not limited to, logic products, memory products, etc. With reference to the attached figures, various illustrative embodiments of the methods and devices disclosed herein will now be described in more detail.

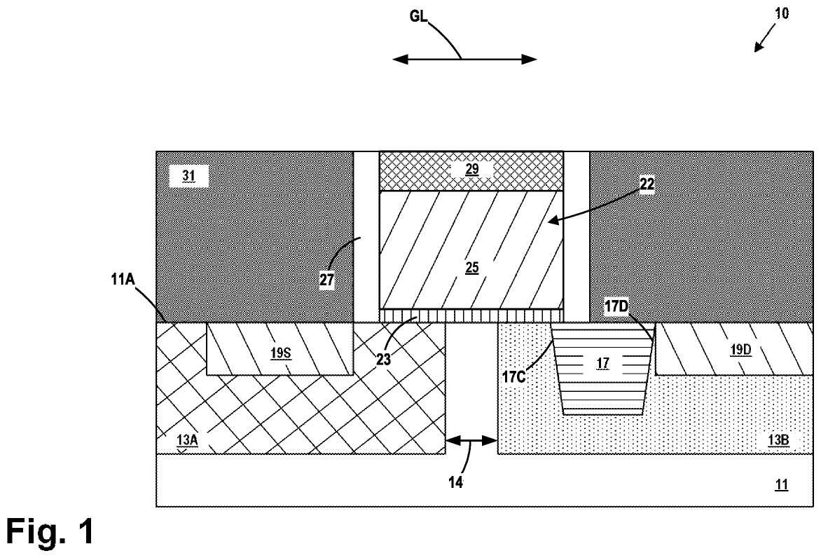

FIGS. 1-11 depict various novel embodiments of a gate structure for an LDMOS (Laterally Diffused Metal Oxide Semiconductor) device 10 and various novel methods of making such a gate structure. As will be appreciated by those skilled in the art after a complete reading of the present application, the LDMOS device 10 disclosed herein may be an N-type or a P-type device. Moreover, the LDMOS device 10 may come in a variety of different forms, e.g., the LDMOS device 10 may be a planar device, a FinFET device, etc. However, the various inventions disclosed herein should not be considered to be limited to the particular example shown in the attached drawings and described below.

The illustrative LDMOS device 10 disclosed herein will be formed above a semiconductor substrate 11 having an upper surface 11A. In the case where the LDMOS device 10 is a FinFET device, the upper surface 11A would be the upper surface of a fin. The gate length (GL) direction of the LDMOS device 10 is also depicted in FIG. 1. The substrate 11 may be a bulk semiconductor substrate or it may be a semiconductor-on-insulator (SOI) substrate that includes a base semiconductor layer, a buried insulation layer and an active semiconductor layer positioned above the buried insulation layer, wherein transistor devices are formed in and above the active semiconductor layer. The substrate (irrespective of its form) may be made of silicon or it may be made of semiconductor materials other than silicon. Thus, the terms “substrate” or “semiconductor substrate” should be understood to cover all semiconducting materials and all forms of such materials. The various components, structures and layers of material depicted herein may be formed using a variety of different materials and by performing a variety of known process operations, e.g., chemical vapor deposition (CVD), atomic layer deposition (ALD), a thermal growth process, spin-coating techniques, etc. The thicknesses of these various layers of material may also vary depending upon the particular application.

FIG. 1 depicts the LDMOS device 10 after several process operations were performed. More specifically, an illustrative P-well 13A and an illustrative N-well 13B (collectively referenced using the numeral 13) were formed in the substrate 11 by performing traditional ion implantation techniques through patterned implant masks (not shown) that were formed above the substrate 11. Of course, the P-well 13A comprises a P-type dopant (e.g., boron) while the N-well 13B comprises an N-type dopant (e.g., arsenic). The concentration of dopant atoms in the wells 13 may vary depending upon the particular application, and the wells 13 need not have the same dopant concentration, but that may be the case in some applications. The physical depth of the wells 13 may vary depending upon the particular application. In the depicted example, the wells 13 are separated by a well gap 14, the magnitude of which may vary depending upon the particular application.

Also depicted in FIG. 1 is an isolation structure 17 that was formed in the substrate 11. The isolation structure 17 may be comprised of a variety of different materials, e.g., silicon dioxide, etc., and it may be formed by performing traditional etching, deposition and planarization processes. The LDMOS device 10 also comprises a source region 19S and a drain region 19D (collectively referenced using the numeral 19). The source region 19S is formed in the P-well 13A, while the drain region 19D is formed in the N-well 13B. In one embodiment, the source/drain regions 19 may be formed by performing traditional ion implantation techniques. In other embodiments (not shown), cavities may be formed in the substrate 11 and a doped epitaxial semiconductor material may be formed in the cavities to form the doped source/drain regions 19.

The gate structure of the LDMOS device 10 will be formed by using replacement gate manufacturing techniques. Accordingly, FIG. 1 depicts the LDMOS device 10 after an initial gate structure 22 was formed above the substrate 11. The initial gate structure 22 comprises a first gate insulation layer 23 and a sacrificial gate electrode 25. An initial gate cap 29 was formed above the sacrificial gate electrode 25. A sidewall spacer 27 was formed adjacent the initial gate structure 22. In an illustrative example, the first gate insulation layer 23 may be comprised of silicon dioxide, silicon nitroxide or silicon nitride and it may be formed by performing a deposition process or by performing a thermal growth process. The sacrificial gate electrode 25 may be comprised of a variety of materials, e.g., amorphous silicon, polysilicon, etc. The initial gate cap 29 may be comprised of a variety of different materials, e.g., silicon nitride. The sidewall spacer 27 may be comprised of a variety of different materials, e.g., silicon dioxide, a low-k material, silicon nitride, SiCN, SiCO, and SiOCN, etc. The sidewall spacer 27 is intended to be representative in nature in that, in some applications, multiple sidewall spacers may be formed adjacent the initial gate structure 22. The vertical thickness of the first gate insulation layer 23, the sacrificial gate electrode 25 and the initial gate cap 29, as well as the lateral thickness of the sidewall spacer 27, may vary depending upon the particular application. In an illustrative embodiment, based upon current-day technology, the first gate insulation layer 23 may have a thickness of about 3-4 nm. The techniques used to form the initial gate structure 22, the initial gate cap 29 and the sidewall spacer 27 are well known to those skilled in the art. The lateral width (critical dimension) of the initial gate structure 22 (in the gate-length direction (GL) of the device) may vary depending upon the particular application.

In a cross-sectional view taken through the isolation structure 17 in a direction corresponding to the gate length direction of the LDMOS device 10, the isolation structure 17 has a channel-side edge 17C and a drain-side edge 17D. As depicted, in an illustrative embodiment, a portion of the isolation structure 17 is positioned vertically below the initial gate structure 22 for the LDMOS device 10. In an illustrative example, the isolation structure 17 may extend under the initial gate structure 22 by a distance of about 30-50 nm based upon current-day technology. Also depicted in FIG. 1 is a layer of insulating material 31 (e.g., an ILD layer) formed across the substrate 11. The layer of insulating material 31 may be formed by performing a blanket deposition process and thereafter performing one or more CMP process operations to planarize the upper surface of the layer of insulating material 31 with the upper surface of the initial gate cap 29. The layer of insulating material 31 may be comprised of a variety of different materials, e.g., silicon dioxide, a low-k material, etc. Although not depicted, in many applications, a conformal contact etch stop layer (CESL), e.g., silicon nitride, would be formed on the substrate 11 prior to the formation of the layer of insulating material 31.

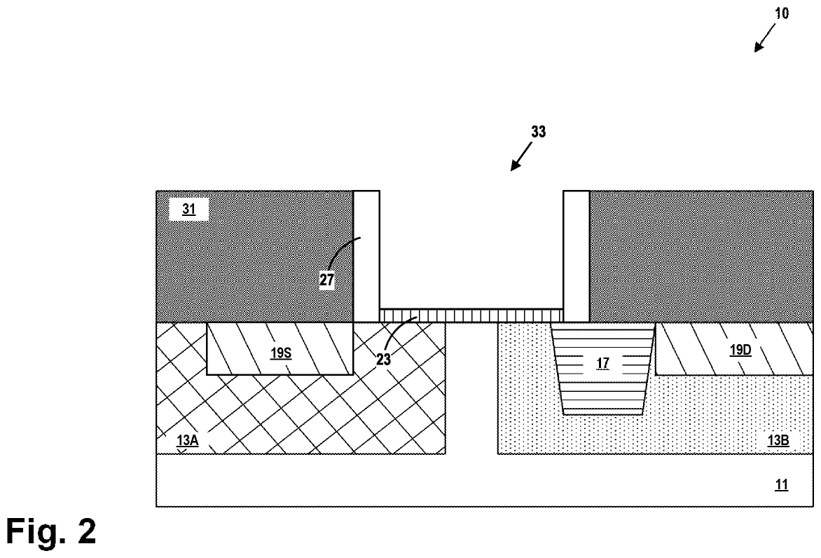

FIG. 2 depicts the LDMOS device 10 after several process operations were performed. First, one or more CMP process operations were performed to remove the initial gate cap 29 to expose the underlying sacrificial gate electrode 25. At that point, an etching process was performed to remove the sacrificial gate electrode 25 selectively relative to the surrounding materials. This results in the formation of a replacement gate cavity 33 that is laterally bounded by the sidewall spacer 27. As depicted, the removal of the sacrificial gate electrode 25 exposes the first gate insulation layer 23.

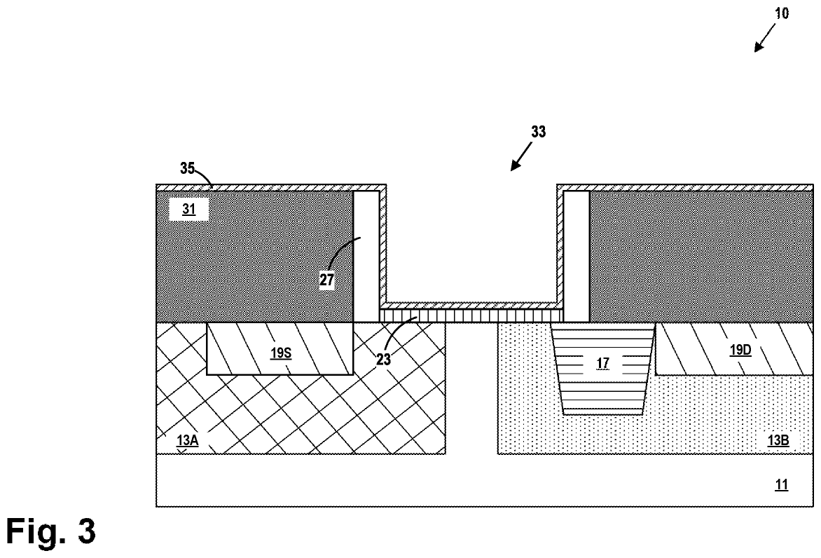

FIG. 3 depicts the LDMOS device 10 after a conformal deposition process (e.g., CVD, ALD, etc.) was performed to form a conformal sacrificial layer of material 35 on the device and within the replacement gate cavity 33. The sacrificial layer of material 35 may be comprised of a variety of different materials, e.g., silicon dioxide, silicon nitride, etc., and it may be formed to any desired thickness, e.g., 3-5 nm.

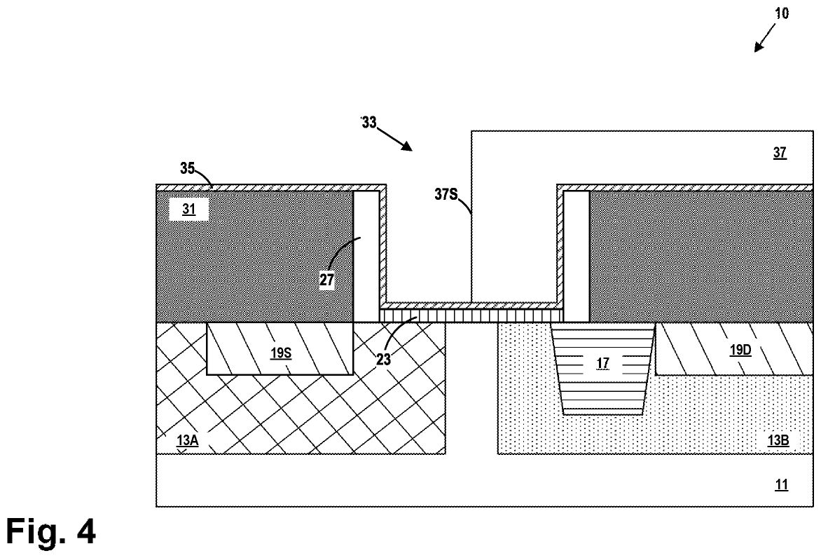

FIG. 4 depicts the LDMOS device 10 after a patterned etch mask 37, e.g., a layer of photoresist or OPL, was formed above the sacrificial layer of material 35. As depicted, the patterned etch mask 37 covers a portion of the sacrificial layer of material 35 while leaving a remaining portion of the sacrificial layer of material 35 exposed for further processing.

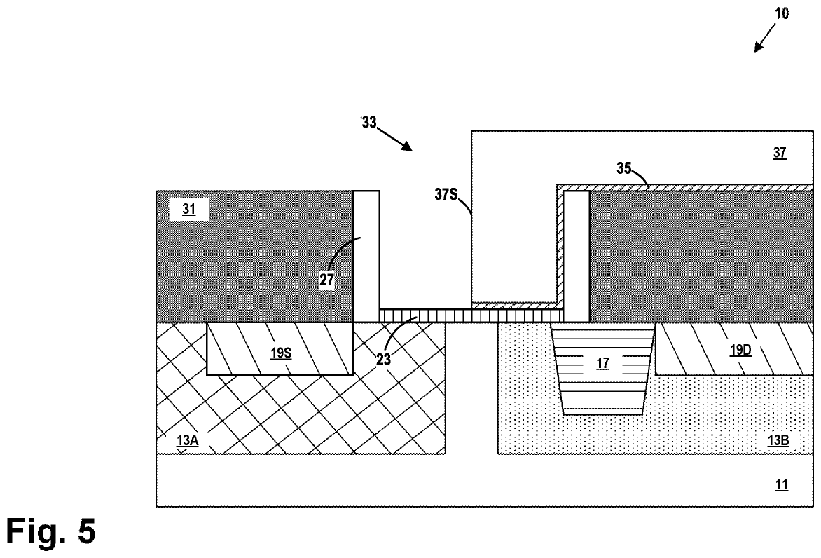

FIG. 5 depicts the LDMOS device 10 after an etching process was performed through the patterned etch mask 37 to remove the exposed portion of the sacrificial layer of material 35. This process exposes a portion of the first gate insulation layer 23.

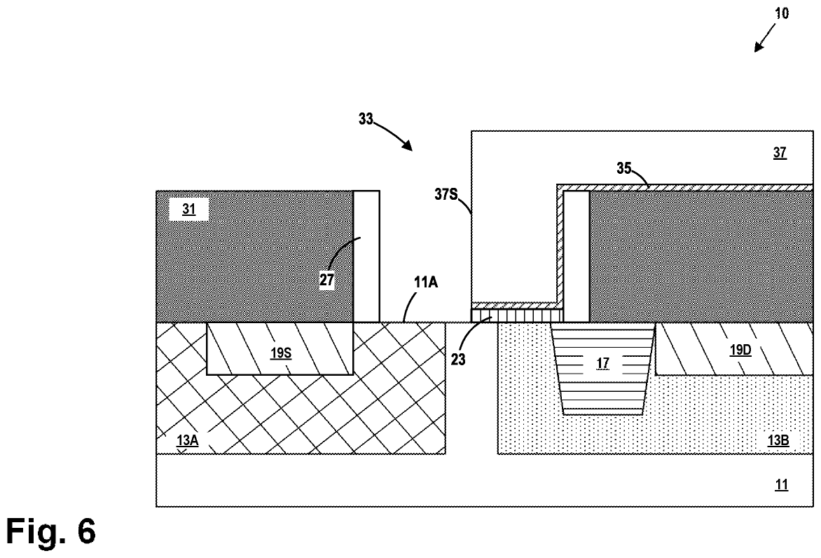

FIG. 6 depicts the LDMOS device 10 after an etching process was performed through the patterned etch mask 37 to remove the exposed portion of the first gate insulation layer 23 within the replacement gate cavity 33. This process exposes a portion of the upper surface 11A of the substrate 11 within the replacement gate cavity 33. As will be described more fully below, the remaining portion of the first gate insulation layer 23 shown in FIG. 6 will be part of the final gate structure for the LDMOS device 10.

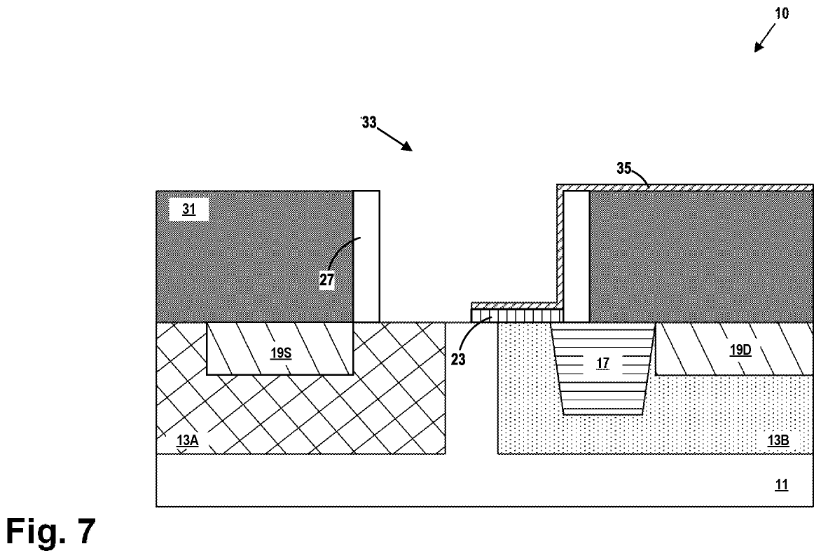

FIG. 7 depicts the LDMOS device 10 after the patterned etch mask 37 was removed, e.g., by performing an ashing process. This process exposes the remaining portion of the sacrificial layer of material 35.

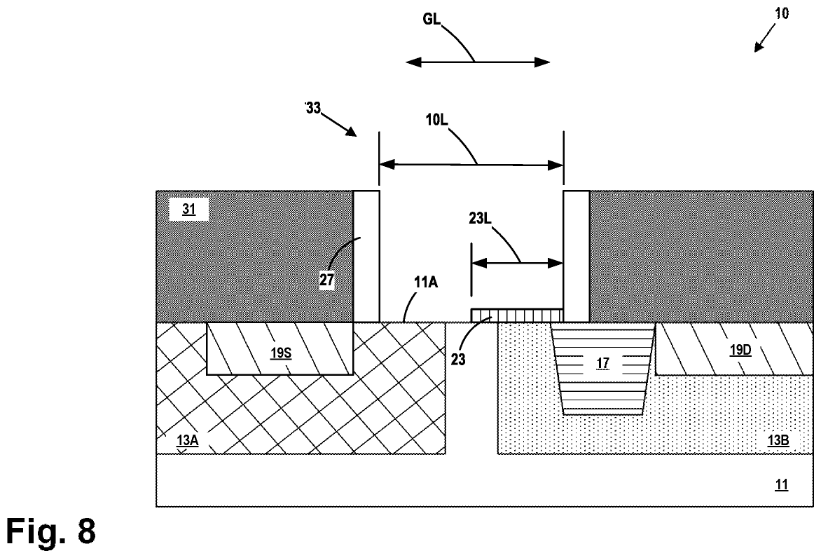

FIG. 8 depicts the LDMOS device 10 after an etching process was performed to remove the remaining portion of the sacrificial layer of material 35 selectively relative to the surrounding materials. This process exposes the remaining portion of the first gate insulation layer 23. The first gate insulation layer 23 has a dimension 23L in the gate length direction of the LDMOS device 10. In an illustrative embodiment, the dimension 23L may be about 200-300 nm based upon current-day technology. Also depicted in FIG. 8 is a dimension 10L that corresponds to the gate length of the LDMOS device 10 (at the surface 11A of the substrate 11). In an illustrative embodiment, the gate length 10L may be about 400-500 nm based upon current-day technology. In terms of percentage, the dimension 23L of the first gate insulation layer 23 may be about 50-80% of the gate length 10L of the transistor device.

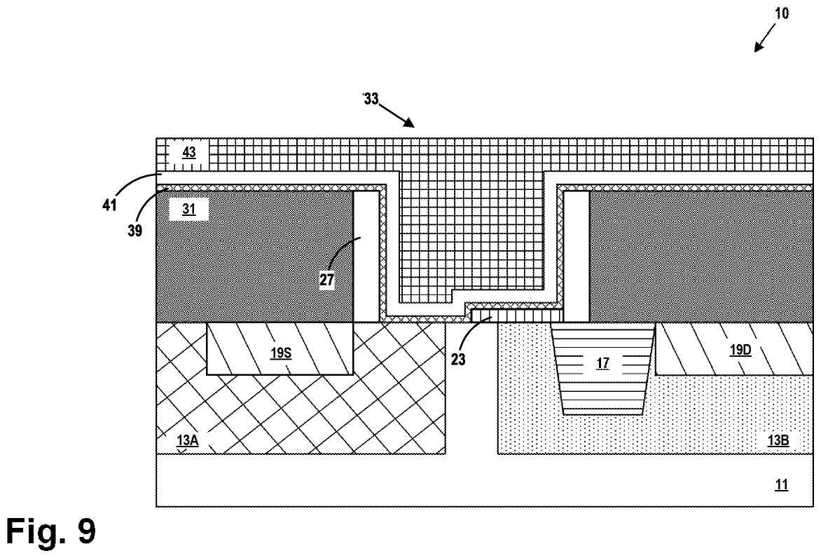

The next major process operation involves the formation of additional materials for the final gate structure of the LDMOS device 10. Accordingly, FIG. 9 depicts the LDMOS device 10 after several process operations were performed. First, a second gate insulation layer 39, a metal-containing layer 41 (e.g., a work function metal layer) and a bulk conductive material layer 43 were sequentially formed on the device 10 and in the replacement gate cavity 33. In practice, there may be more than or less than the three illustrative layers (39, 41 and 43) formed on a real-world LDMOS device 10. The thickness and composition of these gate materials, i.e., the three illustrative layers 39, 41 and 43, may vary depending upon the particular application, and the relative thickness of these gate material layers shown in the drawings is not to scale. For example, in an illustrative embodiment, the second gate insulation layer 39 may be made of a high-k (k value of 10 or greater) insulating material, such as hafnium oxide, while the metal-containing layer 41 may be made of a material such as titanium nitride. The bulk conductive material layer 43 may be comprised of a material such as a metal, a metal alloy, tungsten or a doped polysilicon. The second gate insulation layer 39 and the metal-containing layer 41 may be formed by performing a conformal deposition process, such as an ALD process. The bulk conductive material layer 43 may be formed by performing a blanket deposition process.

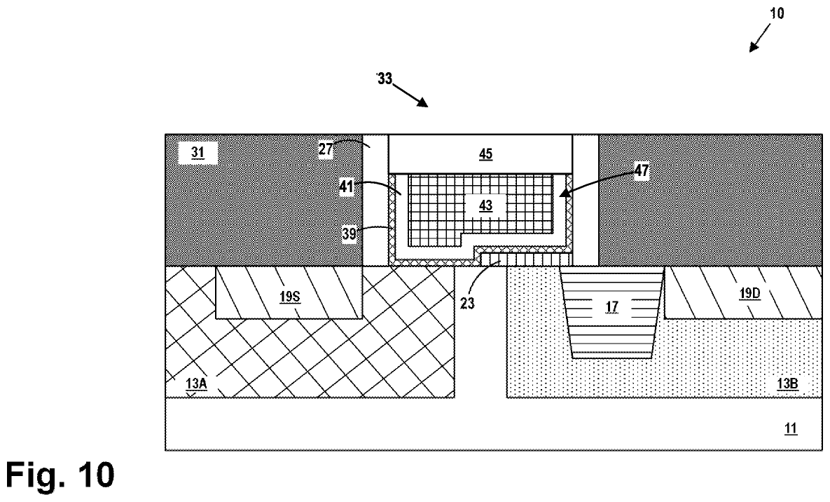

FIG. 10 depicts the LDMOS device 10 after several process operations were performed. First, one or more CMP processes were performed so as to remove excess portions of the various materials of the final gate structure 47 that are positioned above the upper surface of the layer of insulating material 31 and outside of the replacement gate cavity 33. At that point, one or more recess etching processes were performed to recess the vertical height of the materials of the final gate structure 47 so as to make room for a final gate cap 45. The final gate cap 45 may be formed by blanket depositing a layer of the material for the gate cap 45 above the device and in the space above the recessed gate materials for the final gate structure 47 and thereafter performing a CMP process to remove excess amounts of the gate cap material positioned outside the replacement gate cavity 33.

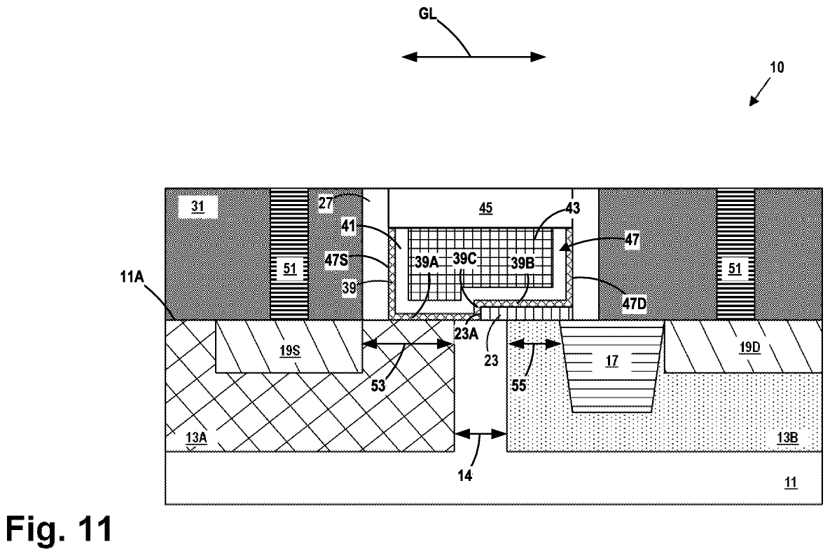

With reference to FIG. 11, after the formation of the final gate structure 47, traditional manufacturing operations are performed to complete the device. For example, conductive source/drain metallization structures 51 (e.g., trench silicide structures, tungsten structures) are formed to contact the source/drain regions 19. In an illustrative embodiment, the source/drain metallization structures 51 may be essentially line-type features that extend into and out of the plan of the drawing in FIG. 11.

The channel region 53 and the drain extension region 55 of the LDMOS device 10 are depicted in FIG. 11. When viewed in a cross-section taken through the final gate structure 47 in the gate length direction of the LDMOS device 10, the final gate structure 47 has a drain-side sidewall 47D and a source-side sidewall 47S. In the illustrative LDMOS device 10 depicted herein, the isolation structure 17 is positioned laterally between the final gate structure 47 and the drain region 19D. As noted previously, in an illustrative embodiment, at least a portion of the isolation structure 17 is positioned vertically under at least a portion of the final gate structure 47 and under at least a portion of the first gate insulation layer 23 of the final gate structure 47.

Also note that, when viewed in the cross-section shown in FIG. 11, the composition of the final gate structure 47 is not uniform across the final gate structure 47, i.e., the first gate insulation layer 23 extends from the drain-side sidewall 47D of the final gate structure 47 to a location above the well gap 14, i.e., a substantially vertically oriented edge 23A of the first gate insulation layer 23 is positioned above the well gap 14. The first gate insulation layer 23 is also positioned vertically above a portion of the drain extension region 55 and a portion of the N-well 13B. In contrast, the second gate insulation layer 39 extends from the source-side sidewall 47S to the drain-side sidewall 47D. Moreover, in an illustrative embodiment, a first portion 39A of the second gate insulation layer 39 is positioned on and in contact with the surface 11A of the substrate 11 above the channel region 53 and a portion of the P-well 13A, while a second portion 39B of the second gate insulation layer 39 is positioned on and in contact with the first gate insulation layer 23. Also note that the first portion 39A of the second gate insulation layer 39 is positioned between the first gate insulation layer 23 and the sidewall spacer 27. The second gate insulation layer 39 also has a third substantially vertically oriented portion 39C that is positioned on and in contact with the substantially vertically oriented edge 23A of the first gate insulation layer 23.

As will be appreciated by those skilled in the art, it is important for LDMOS devices to exhibit good MSG (Maximum Stable Gain) values in power amplifier applications (e.g., a sub-6 GHz WiFi application), particularly in 3.3V LDMOS applications. MSG values for an LDMOS device may be increased by improving the transconductance (gₘ) of the device without significantly increasing the gate-to-drain (C_{gd}) capacitance of the device. Simulation data has revealed that an LDMOS device 10 with the novel final gate structure 47 disclosed herein exhibits better performance characteristics as compared to a prior art LDMOS device with a gate structure wherein a gate insulation layer (corresponding to that of the first gate insulation layer 23) extends across the entire bottom of the gate structure of the prior art LDMOS device. More specifically, by using the novel final gate structure 47 disclosed herein, the LDMOS device 10 described herein exhibited about a 10-15% improvement in MSG at 5 GHz and about a 70-90% improvement in the transconductance (gₘ) as compared to a prior art LDMOS device.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is there-fore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. An LDMOS device, comprising:
a semiconductor substrate having an upper surface;
a source region positioned in a first doped well region in the semiconductor substrate;
a drain region positioned in a second doped well region in the semiconductor substrate, wherein there is a well gap between the first doped well region and the second doped well region; and
a gate structure positioned above the semiconductor substrate, the gate structure comprising:
a source-side sidewall;
a drain-side sidewall;
a first gate insulation layer positioned above the upper surface of the semiconductor substrate, the first gate insulation layer extending from the drain-side sidewall to a location above the well gap; and
a second gate insulation layer, the second gate insulation layer having a first portion positioned above the upper surface of the semiconductor substrate and a second portion positioned above the first gate insulation layer, the first portion extending from the source-side sidewall to the location above the well gap.

2. The LDMOS device of claim 1, wherein:
the first gate insulation layer is positioned above a portion of the second doped well region;
an isolation structure is positioned in the semiconductor substrate laterally between the source region and the drain region, wherein a portion of the isolation structure is positioned vertically below a portion of the first gate insulation layer; and
a drain extension region is below the first gate insulation layer and between the well gap and the isolation structure.

3. (canceled)

4. The LDMOS device of claim 1, wherein the first gate insulation layer comprises one of silicon dioxide, silicon nitroxide, and silicon nitride and wherein the second gate insulation layer comprises a high-k gate insulation layer.

5. The LDMOS device of claim 1, wherein the first gate insulation layer comprises a substantially vertically oriented edge surface positioned above the well gap and wherein a third portion of the second gate insulation layer is positioned on and in physical contact with the substantially vertically oriented edge surface.

6. The LDMOS device of claim 1, wherein the first portion of the second gate insulation layer is positioned between the first gate insulation layer and the source-side sidewall.

7. The LDMOS device of claim 1, wherein the first gate insulation layer is positioned on and in physical contact with the upper surface of the semiconductor substrate, the first portion of the second gate insulation layer is positioned on and in physical contact with the upper surface of the semiconductor substrate and the second portion of the second gate insulation layer is positioned on and in physical contact with the first gate insulation layer.

8. The LDMOS device of claim 1, wherein the second gate insulation layer is a conformal layer of material and wherein the gate structure further comprises at least one conformal metal-containing layer of material positioned above the second gate insulation layer and a conductive material positioned above the at least one conformal metal-containing layer of material.

9. The LDMOS device of claim 1, further comprising at least one fin structure defined in the semiconductor substrate and wherein the LDMOS device is an N-type LDMOS device, wherein the first doped well region is a P-doped well region, the second doped well region is an N-doped well region, the source and drain regions are positioned in the at least one fin structure and the source and drain regions are doped with an N-type dopant material.

10. The LDMOS device of claim 1, wherein the LDMOS device has a gate length at the upper surface of the semiconductor substrate and wherein the first gate insulation layer has a first length in a direction corresponding to the gate length of the LDMOS device, wherein the first length is approximately 50-80% of the gate length of the LDMOS device.

11. An LDMOS device, comprising:
a semiconductor substrate having an upper surface;
a source region positioned in a first doped well region in the semiconductor substrate;
a drain region positioned in a second doped well region in the semiconductor substrate, wherein there is a well gap between the first doped well region and the second doped well region; and
a gate structure positioned above the semiconductor substrate, the gate structure comprising:
a source-side sidewall;
a drain-side sidewall;
a first gate insulation layer positioned on and in physical contact with the upper surface of the semiconductor substrate and above a portion of the second doped well region; and
a second gate insulation layer, the second gate insulation layer having a first portion and a second portion, wherein the first portion is positioned on and in physical contact with the upper surface of the semiconductor substrate, the second portion is positioned on and in physical contact with an upper surface of the first gate insulation layer and wherein the first portion of the second gate insulation layer is positioned between the first gate insulation layer and the source-side sidewall, the first portion extending from the source-side sidewall to the location above the well gap.

12. The LDMOS device of claim 11, further comprising an isolation structure positioned in the semiconductor substrate laterally between the source region and the drain region, wherein a portion of the isolation structure is positioned vertically below a portion of the first gate insulation layer.

13. (canceled)

14. The LDMOS device of claim 11, wherein the second gate insulation layer is a conformal layer of material and wherein the gate structure further comprises at least one conformal metal-containing layer of material positioned above the second gate insulation layer and a conductive material positioned above the at least one conformal metal-containing layer of material.

15. A method of forming a gate structure, the method comprising:
forming an initial gate structure above a semiconductor substrate, the initial gate structure comprising a first gate insulation layer positioned on the semiconductor substrate between a sidewall spacer;
forming a patterned etch-mask, the patterned etch-mask covering a first portion of the first gate insulation layer while leaving a second portion of the first gate insulation layer exposed;
performing an etching process to remove the second portion of the first gate insulation layer;
removing the patterned etch-mask; and
forming a conformal second gate insulation layer, the conformal second gate insulation layer having a first portion positioned on the upper surface of the semiconductor substrate and a second portion positioned on the first gate insulation layer, the first portion extending from the source-side sidewall to the location above the well gap.

16. The method of claim 15, further comprising:
forming a first doped well region in the semiconductor substrate;
forming a source region in the first doped well region;
forming a second doped well region in the semiconductor substrate, wherein there is a well gap between the first doped well region and the second doped well region and wherein the first gate insulation layer is positioned above a portion of the second doped well region; and
forming a drain region in the second doped well region.

17. The method of claim 16, further comprising forming an isolation structure in the semiconductor substrate laterally between the source region and the drain region, wherein a portion of the isolation structure is positioned vertically below a portion of the first gate insulation layer.

18. The method of claim 16, wherein the first gate insulation layer comprises a substantially vertically oriented edge surface positioned above the well gap and wherein forming the conformal second gate insulation layer comprises forming the conformal second gate insulation layer such that a third portion of the second conformal gate insulation layer is positioned on and in physical contact with the substantially vertically oriented edge surface.

19. The method of claim 15, wherein the gate structure comprises a source-side sidewall and wherein forming the conformal second gate insulation layer comprises forming the conformal second gate insulation layer such that the first portion of the conformal second gate insulation layer is positioned between the first gate insulation layer and the source-side sidewall.

20. The method of claim 16, wherein the gate structure comprises a drain-side sidewall and wherein forming the first gate insulation layer comprises forming the first gate insulation layer such that the first gate insulation layer extends from the drain-side sidewall to a location above the well gap.
